(19) United States
(12) Patent Application Publication
(10) Pub. No.: US 2012/0064676 A1
(43) Pub. Date: Mar. 15, 2012

(54) METHOD OF FABRICATING THIN FILM TRANSISTOR

(75) Inventors: Hye-Hyang PARK, Suwon-si (KR); Byoung-Deog Choi, Suwon-si (KR); Dae-Woo Lee, Suwon-si (KR); Chang-Young Jeong, Suwon-si (KR); Moo-Jin Kim, Suwon-si (KR); Kyoung-Bo Kim, Suwon-si (KR)

(73) Assignee: SAMSUNG MOBILE DISPLAY CO., LTD., Suwon-si (KR)

(21) Appl. No.: 13/301,032

(22) Filed: Nov. 21, 2011

Related U.S. Application Data
(62) Division of application No. 11/987,951, filed on Dec. 6, 2007.

(30) Foreign Application Priority Data
Dec. 6, 2006 (KR) 10-2006-0123043

(51) Int. Cl. H01L 21/336

(52) U.S. Cl. 438/151; 257/E21.411

(57) ABSTRACT

A thin film transistor includes a substrate, a semiconductor layer on the substrate, a thermal oxide layer on the semiconductor layer, a gate electrode on the thermal oxide layer, the gate electrode positioned to correspond to a channel region of the semiconductor layer, an interlayer insulating layer on the substrate, and source and drain electrodes electrically connected to the semiconductor layer.

### CROSS REFERENCE TO RELATED APPLICATION

This is a divisional application based on pending application Ser. No. 11/987,951, filed Dec. 6, 2007, the entire contents of which is hereby incorporated by reference.

### BACKGROUND OF THE INVENTION

1. Field of the Invention

Embodiments of the present invention relate to a thin film transistor, a method of fabricating the same, and a display device including the same. More particularly, embodiments of the present invention relate to a thin film transistor with a thermal oxide layer functioning as a gate insulating layer, a method of fabricating the same, and a display device including the same.

2. Description of the Related Art

In general, fabricating a thin film transistor (TFT) may include depositing amorphous silicon on a substrate, e.g., glass, quartz, and/or plastic, and crystallizing the amorphous silicon to form a semiconductor layer. A gate insulating layer may be deposited on the semiconductor layer, followed by formation of a gate electrode, an interlayer insulating layer, and source/drain electrodes may thereon to complete the TFT.

Conventional methods of depositing the gate insulating layer on the crystallized semiconductor layer may include depositing, e.g., a silicon oxide layer or a silicon nitride layer, via, e.g., a chemical vapor deposition (CVD) method. However, the conventional CVD method may form non-uniform layers and quality of a layer formed by the conventional CVD method may be degraded. Hence, when the gate insulating layer is deposited by the conventional CVD method, the gate insulating layer should be deposited to a high thickness, e.g., about 1000 angstroms or more. High thickness of the gate insulating layer may unnecessarily increase an overall size of the TFT, thereby reducing the degree of integration thereof. Further, non-uniformity of the gate insulating layer may trigger insulation breakdown, thereby increasing leakage current density, which in turn may reduce operability and reliability of the TFT.

Accordingly, there exists a need for an improved structure of a TFT and a method of fabricating the same in order to provide a TFT with enhanced electrical characteristics and reliability.

### SUMMARY OF THE INVENTION

Embodiments of the present invention are therefore directed to a thin film transistor (TFT), a method of fabricating the same, and a display device including the same, which substantially overcome one or more of the disadvantages of the related art.

It is therefore a feature of an embodiment of the present invention to provide a TFT with a thermal oxide layer.

It is another therefore a feature of an embodiment of the present invention to provide a method of fabricating a TFT with a thermal oxide layer.

It is still another feature of an embodiment of the present invention to provide a display device including a TFT with a thermal oxide layer.

At least one of the above and other features and advantages of the present invention may be realized by providing a TFT including a substrate, a semiconductor layer on the substrate, a thermal oxide layer on the semiconductor layer, a gate electrode on the thermal oxide layer, the gate electrode positioned to correspond to a channel region of the semiconductor layer, an interlayer insulating layer on the substrate, and source and drain electrodes electrically connected to the semiconductor layer.

The thermal oxide layer may include silicon oxide. The thermal oxide layer may have a thickness of about 50 angstroms to about 300 angstroms. The thermal oxide layer may include a gate insulating layer. The gate electrode may be directly on the thermal oxide layer. The TFT may further include a buffer layer between the substrate and the semiconductor layer. The semiconductor layer may be encapsulated between the buffer layer and the thermal oxide layer

At least one of the above and other features and advantages of the present invention may be further realized by providing a method of fabricating a TFT, including forming a semiconductor layer on a substrate, forming a thermal oxide layer on the semiconductor layer in an H₂O atmosphere, forming a gate electrode on the thermal oxide layer, the gate electrode positioned to correspond to a channel region of the semiconductor layer, forming an interlayer insulating layer on the substrate, and forming source and drain electrodes electrically connected to the semiconductor layer.

Forming the semiconductor layer may include crystallizing amorphous silicon to form a polysilicon layer and patterning the polysilicon layer. Crystallizing the amorphous silicon layer may include using one or more of a solid phase crystallization (SPC) method, a sequential lateral solidification (SLS) method, an excimer laser annealing (ELA) method, a metal induced crystallization (MIC) method, and/or a metal induced lateral crystallization (MILC) method. After crystallizing and patterning the semiconductor layer, the thermal oxide layer may be formed using annealing in an H₂O atmosphere. Forming the thermal oxide layer may include annealing the semiconductor layer in an H₂O atmosphere. Annealing the semiconductor layer may include using a rapid thermal annealing (RTA) method. Annealing the semiconductor layer may be performed at a temperature of about 550° C. to about 750° C. Annealing the semiconductor layer may include setting the H₂O atmosphere at a pressure of about 0.01 MPa to about 2 MPa. Annealing the semiconductor layer may include forming the thermal oxide layer to a thickness of about 50 angstroms to about 300 angstroms. The method may further include forming a buffer layer between the substrate and the semiconductor layer.

At least one of the above and other features and advantages of the present invention may be also realized by providing a display device, including a semiconductor layer on a substrate, a thermal oxide layer on the semiconductor layer, a gate electrode on the thermal oxide layer, the gate electrode positioned to correspond to a channel region of the semiconductor layer, an interlayer insulating layer on the substrate, source and drain electrodes electrically connected to the semiconductor layer, and a light source electrically connected to one of the source and drain electrodes. The thermal oxide layer may include silicon oxide. The light source may be an organic light emitting diode.

### BRIEF DESCRIPTION OF THE DRAWINGS

The above and other features and advantages of the present invention will become more apparent to those of ordinary skill in the art by describing in detail exemplary embodiments thereof with reference to the attached drawings, in which:

FIGS. 1A-1E illustrate cross-sectional views of sequential stages in a fabrication process of a thin film transistor in accordance with an exemplary embodiment of the present invention; and

FIG. 1F illustrates a cross-sectional view of an electroluminescent display device in accordance with an exemplary embodiment of the present invention.

### DETAILED DESCRIPTION OF THE INVENTION

Korean Patent Application No. 10-2006-0123043, filed on Dec. 6, 2006, in the Korean Intellectual Property Office, and entitled: “Thin Film Transistor, Method of Fabricating the Same, and Organic Light Emitting Diode Display Device Including the Same,” is incorporated by reference herein in its entirety.

Embodiments of the present invention will now be described more fully hereinafter with reference to the accompanying drawings, in which exemplary embodiments of the invention are illustrated. Aspects of the invention may, however, be embodied in different forms and should not be construed as limited to the embodiments set forth herein. Rather, these embodiments are provided so that this disclosure will be thorough and complete, and will fully convey the scope of the invention to those skilled in the art.

In the figures, the dimensions of layers and regions may be exaggerated for clarity of illustration. It will also be understood that when a layer or element is referred to as being “on” another layer or substrate, it can be directly on the other layer or substrate, or intervening layers may also be present. Further, it will be understood that when a layer is referred to as being “under” another layer, it can be directly under, and one or more intervening layers may also be present. In addition, it will also be understood that when a layer is referred to as being “between” two layers, it can be the only layer between the two layers, or one or more intervening layers may also be present. Like reference numerals refer to like elements throughout.

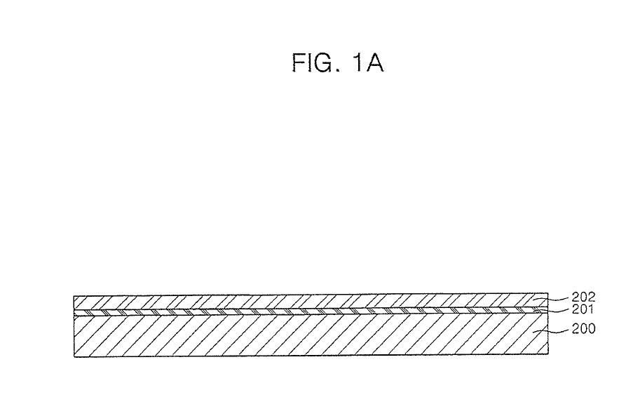

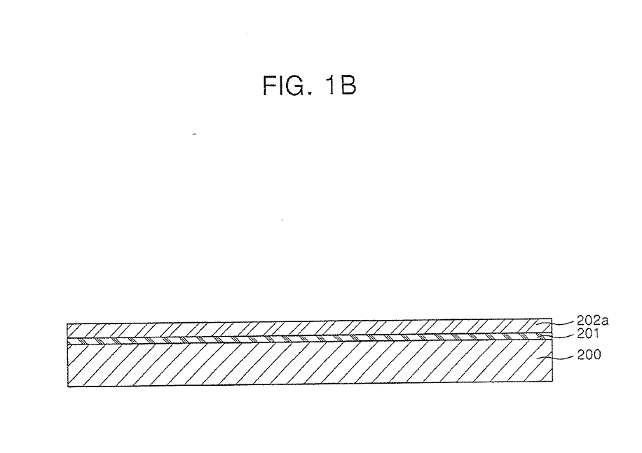

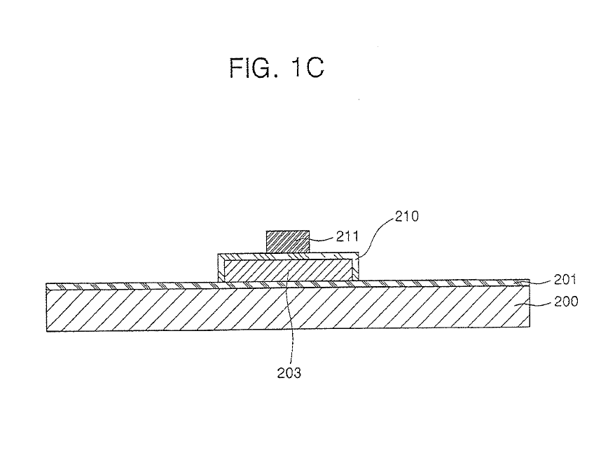

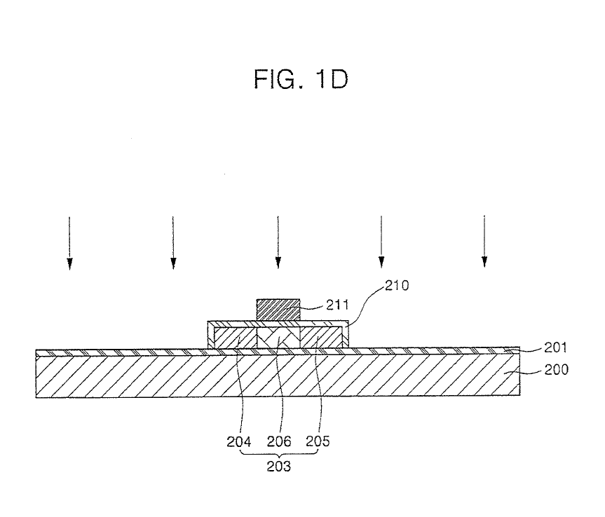

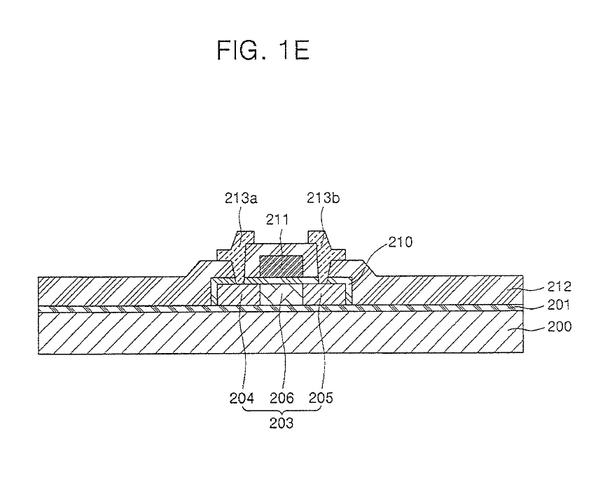

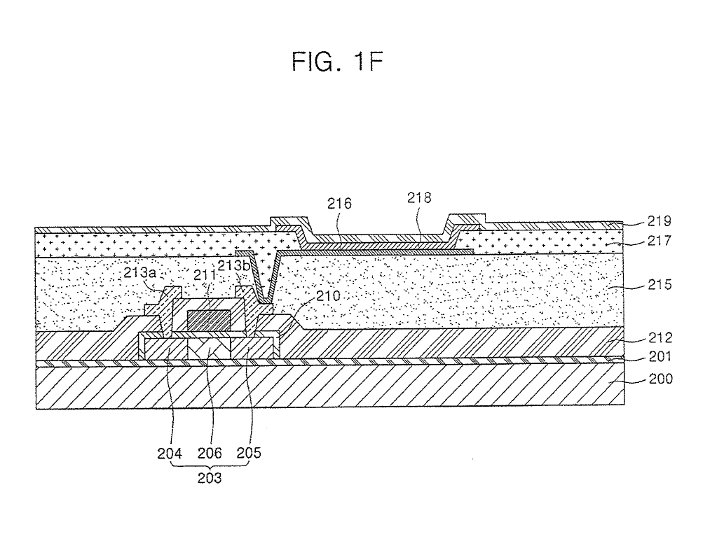

Exemplary embodiments of a thin film transistor (TFT) and a method of fabricating the same according to the present invention will be described in more detail below with reference to FIGS. 1A-1E.

Referring to FIG. 1A, a buffer layer 201 may be formed on a substrate 200. The substrate 200 may be transparent, e.g., insulating glass, quartz, or plastic. The buffer layer 201 may substantially minimize or prevent diffusion of moisture and/or impurities from the substrate 200 in an upward direction, i.e., toward upper layers. Additionally, the buffer layer 201 may adjust a heat transfer rate during, e.g., crystallization. The buffer layer 201 may include a silicon oxide layer, a silicon nitride layer, or a combination thereof.

Next, an amorphous silicon layer 202 may be formed on the buffer layer 201. The amorphous silicon layer 202 may be deposited on the buffer layer 201 by, e.g., a plasma enhanced chemical vapor deposition (PECVD) method, a low pressure chemical vapor deposition (LPCVD) method, and so forth. If the PECVD method is used, a temperature of about 330° C. to about 430° C. and a pressure of about 1 Torr to about 1.5 Torr in an atmosphere containing silane (SiH₄) and/or hydrogen (H₂) in argon (Ar) may be employed. If the LPCVD method is used, a temperature of about 400° C. to about 500° C. and a pressure of about 0.2 Torr to about 0.4 Torr in an atmosphere of disilane (Si₂H₆) in argon (Ar) may be employed.

Next, as illustrated in FIG. 1B, the amorphous silicon layer 202 may be crystallized to form a polysilicon layer 202a. More specifically, formation of the polysilicon layer 202a may be performed using one or more of a solid phase crystallization (SPC) method, a sequential lateral solidification (SLS) method, an excimer laser annealing (ELA) method, a metal induced crystallization (MIC) method, and/or a metal induced lateral crystallization (MILC) method. Subsequently, as illustrated in FIG. 1C, the polysilicon silicon layer 202a may be patterned to form a semiconductor layer 203. Once the semiconductor layer 203 is formed, a thermal process may be performed thereon to form a thermal oxide layer 210. More specifically, the semiconductor layer 203 may be annealed, so an outer surface thereof may be thermally oxidized to form the thermal oxide layer 210.

Annealing of the semiconductor layer 203 may be performed in a presence of water vapor (H₂O), i.e., in an H₂O atmosphere, and may include, e.g., a rapid thermal annealing (RTA) method or furnace annealing. Annealing in an H₂O atmosphere may be advantageous, as compared to annealing in an atmosphere containing, e.g., a nitrogen gas (N₂) and/or an oxygen gas (O₂). In particular, use of the H₂O atmosphere during the annealing process may provide a substantially reduced annealing time for a predetermined annealing temperature, as compared to annealing in N₂ and/or O₂ atmospheres at a substantially same predetermined annealing temperature. Similarly, use of the H₂O atmosphere during the annealing process may provide a substantially reduced annealing temperature for a predetermined annealing time, as compared to annealing in N₂ and/or O₂ atmospheres at a substantially same predetermined annealing time. In particular, such reduced annealing time and/or temperature may substantially minimize exposure of the, e.g., substrate 200 and/or semiconductor layer 203, to heat, thereby substantially minimizing or preventing deformation thereof.

The annealing may be performed at a temperature of about 550° C. to about 750° C., and at H₂O pressure of about 0.01 MPa to about 2 MPa. A temperature below about 550° C. may be insufficient to form a thermal oxide layer. A temperature above about 750° C. may be too high, thereby causing material deformation. In addition, within the temperature of about 600° C. to about 710° C., it is possible to obtain good thermal oxide layers for an appropriate annealing time A pressure below about 0.01 MPa may lower a formation speed of a thermal oxide layer, thereby increasing annealing process time. A pressure above about 2 MPa may be too high, thereby risking a potential explosion.

The thermal oxide layer 210 may be formed on an upper surface and on lateral surfaces of the semiconductor layer 203 by thermal oxidation, so the thermal oxide layer 210 and the semiconductor layer 203 may be integral with one another. The thermal oxide layer 210 may be in direct contact with the buffer layer 201 around the periphery of the semiconductor layer 203, so the semiconductor layer 203 may be entirely encapsulated between the buffer layer 201 and the thermal oxide layer 210, as illustrated in FIG. 1C. The thermal oxide layer 210 may have a single-layer structure, and may be formed to a thickness of about 50 angstroms to about 300 angstroms. A thickness below about 50 angstroms may be insufficient to provide sufficient insulation to a gate electrode 211, and a thickness above about 300 angstroms may increase manufacturing time and TFT size. In this respect, it should be noted that the annealing temperature and/or processing time may be adjusted within the ranges indicated above in order to form the thermal oxide layer 210 with a thickness of about 50 angstroms to about 300 angstroms. It is further noted that the annealing process may facilitate formation of the thermal oxide layer 210 with a uniform thickness, thereby providing a layer capable of both exhibiting sufficient electrical properties, e.g., insulation, and low thickness. The thermal oxide layer 210 may function as a gate insulating layer.

Then, a gate electrode metal layer (not shown) may be formed on the thermal oxide layer 210. The gate electrode metal layer may have a single layer structure, e.g., an aluminum (Al) layer or an Al alloy layer, e.g., an aluminum-neodymium (Al—Nd) layer. Alternatively, the gate electrode metal layer may have a multi-layer structure, e.g., an Al alloy layer on a metal layer, e.g., chromium (Cr), molybdenum (Mo), and/or alloys thereof. Next, the gate electrode metal layer may be etched to form the gate electrode 211 in a predetermined area on the thermal oxide layer 210, e.g., in an area corresponding to a channel region of the semiconductor layer 203, as illustrated in FIG. 1C. The gate electrode 211 may be formed directly on the thermal oxide layer 210.

Referring to FIG. 1D, a predetermined amount of conductive impurity ions may be injected into the semiconductor layer 203 to form source and drain regions 204 and 205, respectively. A channel region 206 may be formed in the semiconductor layer 203 between the source and drain regions 204 and 205 using the gate electrode 211 as a mask. The impurity ions may include p-type impurities, e.g., boron (B) ions, aluminum (Al) ions, gallium (Ga) ions, indium (In) ions, and so forth, or n-type impurities, e.g., phosphorous (P) ions, arsenic (As) ions, antimony (Sb) ions, and so forth.

Then, referring to FIG. 1E, an interlayer insulating layer 212 may be formed on an entire upper surface of the substrate 200 to coat upper surfaces of the buffer layer 201, thermal oxide layer 210, and gate electrode 211. Next, as further illustrated in FIG. 1E, predetermined regions of the interlayer insulating layer 212 and thermal oxide layer 210 may be etched to form contact holes therethrough, so source and drain electrodes 213a and 213b formed on the interlayer insulating layer 212 may be electrically connected through the contact holes to the source and drain regions 204 and 205 of the semiconductor layer 203, thereby completing formation of a TFT.

The TFT formed according to an embodiment of the present invention may reduce the thickness of the gate insulating layer to 300 Å or less using the thermal oxide layer 210, thereby improving operability and reliability of the TFT. Further, according to an embodiment of the present invention, reduced annealing time and/or temperature may substantially minimize exposure of the, e.g., substrate 200 and/or semiconductor layer 203, to heat, thereby substantially minimizing or preventing deformation thereof by annealing in an H₂O atmosphere.

The TFT described previously in FIGS. 1A-1E may be employed in a display device. For example, as illustrated in FIG. 1F, the TFT may be used as a switching device in an electroluminescent (EL) display, e.g., an organic light emitting diode (OLED) display device. More specifically, as further illustrated in FIG. 1F, a planarization layer 215 and a light emitting diode (LED), i.e., a first electrode 216, a light emitting layer 218, and a second electrode 219, may be deposited on the substrate 200.

The planarization layer 215 may be formed on the entire upper surface of the substrate 200 of an organic layer, e.g., an acryl-based resin, a polyimide-based resin, and/or a benzocyclobutene (BCB), an inorganic layer, e.g., spin on glass (SOG), or a composite layer thereof. Next, the planarization layer 215 may be etched to form a via-hole therethrough to expose one of the source and drain electrodes 213a and 213b.

The first electrode 216 of the LED may be formed on the planarization layer 215, and may be connected through the via-hole to one of the source and drain electrodes 213a and 213b. The first electrode 216 may be formed of, e.g., indium tin oxide (ITO) or indium zinc oxide (IZO).

Then, a pixel-defining layer 217 may be formed on the planarization layer 215 and first electrode 216, and the via-hole may be filled therewith. The pixel-defining layer 217 may be formed of an inorganic material or an organic material, e.g., benzocyclobutene (BCB), an acryl-based polymer, and/or a polyimide, in order to exhibit good flowability, i.e., provide a uniformly flat surface on the planarization layer 215. Next, the pixel-defining layer 217 may be etched to form an opening therethrough to expose an upper surface of the first electrode 216.

Subsequently, the light emitting layer 218 may be formed on the first electrode 216. The light emitting layer 218 may be formed of an organic material, and may include an emission layer, a hole injection layer, a hole transport layer, an electron transport layer, and an electron injection layer. Then, the second electrode 219 may be formed on the light emitting layer 218 to be in contact with the pixel-defining layer 217 in order to complete the LED. The second electrode 219 may be a transmissive electrode formed of a material having a low work function, e.g., magnesium (Mg), silver (Ag), aluminum (Al), calcium (Ca), and/or an alloy thereof.

According to embodiments of the present invention a TFT, a method of fabricating the same, and a display device including the same may provide a gate insulating layer having improved electrical characteristics, thereby providing improved operability and reliability to the TFT and display device including the same.

Exemplary embodiments of the present invention have been disclosed herein, and although specific terms are employed, they are used and are to be interpreted in a generic and descriptive sense only and not for purpose of limitation. Accordingly, it will be understood by those of ordinary skill in the art that various changes in form and details may be made without departing from the spirit and scope of the present invention as set forth in the following claims.

1.-7. (canceled)

8. A method of fabricating a thin film transistor (TFT), comprising:
forming a semiconductor layer on a substrate;
forming a thermal oxide layer on the semiconductor layer in an H₂O atmosphere;
forming a gate electrode on the thermal oxide layer, the gate electrode positioned to correspond to a channel region of the semiconductor layer;
forming an interlayer insulating layer on the substrate; and
forming source and drain electrodes electrically connected to the semiconductor layer.

9. The method as claimed in claim 8, wherein forming the semiconductor layer includes crystallizing amorphous silicon to form a polysilicon layer and patterning the polysilicon layer.

10. The method as claimed in claim 9, wherein crystallizing the amorphous silicon layer includes using one or more of a solid phase crystallization (SPC) method, a sequential lateral solidification (SLS) method, an excimer laser annealing (ELA) method, a metal induced crystallization (MIC) method, and/or a metal induced lateral crystallization (MILC) method.

11. The method as claimed in claim 10, wherein after crystallizing and patterning the polysilicon layer, the thermal oxide layer is formed using annealing in an H₂O atmosphere.

12. The method as claimed in claim 8, wherein forming the thermal oxide layer includes annealing the semiconductor layer in an H₂O atmosphere.

13. The method as claimed in claim 12, wherein annealing the semiconductor layer includes using a rapid thermal annealing (RTA) method.

14. The method as claimed in claim 12, wherein annealing the semiconductor layer is performed at a temperature of about 550° C. to about 750° C.

15. The method as claimed in claim 12, wherein annealing the semiconductor layer includes setting the H₂O atmosphere at a pressure of about 0.01 MPa to about 2 MPa.

16. The method as claimed in claim 12, wherein annealing the semiconductor layer includes forming the thermal oxide layer to a thickness of about 50 angstroms to about 300 angstroms.

17. The method as claimed in claim 8, further comprising forming a buffer layer between the substrate and the semiconductor layer.

18.-20. (canceled)
